(19) United States
(12) Patent Application Publication
(10) Pub. No.: US 2012/0094407 A1
(43) Pub. Date: Apr. 19, 2012

(54) WAFER LEVEL LED PACKAGE STRUCTURE FOR INCREASING LIGHT-EMITTING EFFICIENCY AND HEAT-DISSIPATING EFFECT AND METHOD FOR MANUFACTURING THE SAME

(75) Inventors: BILY WANG, HSIN CHU CITY (TW); JONNIE CHUANG, TAIPEI HSIEN (TW); CHUAN-FA LIN, TAIPEI HSIEN (TW); CHI-WEN HUNG, TAO YUAN HSIEN (TW)

(73) Assignee: HARVATEK CORPORATION, HSIN CHU CITY (TW)

(21) Appl. No.: 13/328,083

(22) Filed: Dec. 16, 2011

Related U.S. Application Data
(62) Division of application No. 12/856,968, filed on Aug. 16, 2010.
Application No. 12/856,968 is a continuation-in-part of application No. 11/488,764, filed on Jul. 19, 2006, now abandoned.
Application No. 11/488,764 is a continuation-in-part of application No. 11/041,952, filed on Jan. 26, 2005, now Pat. No. 7,655,997.

(51) Int. Cl. H01L 33/62

(52) U.S. Cl. 438/27; 257/E33.056

(57) ABSTRACT

A wafer level LED package structure includes a light-emitting unit, a reflecting unit, a first conductive unit and a second conductive unit. The light-emitting unit has a substrate body, a light-emitting body disposed on the substrate body, a positive and a negative conductive layers formed on the light-emitting body, and a light-emitting area formed in the light-emitting body. The reflecting unit has a reflecting layer formed between the positive and the negative conductive layers and on the substrate body for covering external sides of the light-emitting body. The first conductive unit has a first positive conductive layer formed on the positive conductive layer and a first negative conductive layer formed on the negative conductive layer. The second conductive unit has a second positive conductive structure formed on the first positive conductive layer and a second negative conductive structure formed on the first negative conductive layer.

### CROSS REFERENCE TO RELATED APPLICATION

This Application is a Divisional of application Ser. No. 12/856,968, filed on 16 Aug. 2010, now pending, which is a Continuation-in-Part of application Ser. No. 11/488,764, filed on 19 Jul. 2006, and entitled “WAFER-LEVEL ELECTRO-OPTICAL SEMICONDUCTOR MANUFACTURE FABRICATION METHOD”, which is abandoned, which was a Continuation-in-Part of application Ser. No. 11/041,952, filed on 26 Jan. 2005, now U.S. Pat. No. 7,655,997, issued on 2 Feb. 2010.

### BACKGROUND OF THE INVENTION

1. Field of the Invention

The present invention relates to a wafer level LED package structure and a method for manufacturing the same, in particular, to a wafer level LED package structure for increasing light-emitting efficiency and heat-dissipating effect and a method for manufacturing the same.

2. Description of Related Art

The invention of the lamp greatly changed the style of building construction and the living style of human beings, allowing people to work during the night. Without the invention of the lamp, we may stay in the living conditions of ancient civilizations.

Various lamps such as incandescent bulbs, fluorescent bulbs, power-saving bulbs and etc. have been intensively used for indoor illumination. These lamps commonly have the disadvantages of quick attenuation, high power consumption, high heat generation, short working life, high fragility, and being not recyclable. Hence, LED package structure is created in order to solve the above-mentioned questions of the prior lamps.

Referring to FIG. 1, the related art discloses an LED package structure including a light-emitting body 11a, a positive conductive layer Pa and a negative conductive layer Na both disposed on the light-emitting body 11a, three layers such as an ITO layer, a SiO₂ layer and a Ti/Al/Ti/Au layer (reflecting layer) stacked onto each other, a photoresist layer 2a formed between the positive conductive layer Pa and the negative conductive layer Na and covering the external sides of the positive conductive layer Pa and the negative conductive layer Na, and two conductive layers 3a respectively disposed on the positive conductive layer Pa and the negative conductive layer Na.

### SUMMARY OF THE INVENTION

In view of the aforementioned issues, the present invention provides a wafer level LED package structure for increasing light-emitting efficiency and heat-dissipating effect and a method for manufacturing the same.

To achieve the above-mentioned objectives, the present invention provides a wafer level LED package structure for increasing light-emitting efficiency and heat-dissipating effect, including: a light-emitting unit, a reflecting unit, a first conductive unit and a second conductive unit. The light-emitting unit has a substrate body, a light-emitting body disposed on the substrate body, a positive conductive layer and a negative conductive layer both formed on the light-emitting body, and a light-emitting area formed in the light-emitting body. The reflecting unit has a reflecting layer formed between the positive conductive layer and the negative conductive layer and on the substrate body for covering external sides of the light-emitting body. The first conductive unit has a first positive conductive layer formed on the positive conductive layer and a first negative conductive layer formed on the negative conductive layer. The second conductive unit has a second positive conductive structure formed on the first positive conductive layer and a second negative conductive structure formed on the first negative conductive layer.

To achieve the above-mentioned objectives, the present invention provides a method for making a wafer level LED package structure for increasing light-emitting efficiency and heat-dissipating effect, including: providing a wafer having a plurality of light-emitting units, wherein each light-emitting unit has a substrate body, a light-emitting body disposed on the substrate body, a positive conductive layer and a negative conductive layer both formed on the light-emitting body, and a light-emitting area formed in the light-emitting body; cutting one part of the light-emitting body in order to expose peripheral area of a top surface of the substrate body; forming a reflecting layer between the positive conductive layer and the negative conductive layer and on the peripheral area of the top surface of the substrate body in order to cover external sides of the light-emitting body and expose the positive conductive layer and the negative conductive layer; respectively forming a plurality of first conductive units on the light-emitting units, wherein each first conductive unit has a first positive conductive layer formed on the corresponding positive conductive layer and a first negative conductive layer formed on the corresponding negative conductive layer; and respectively forming a plurality of second conductive units on the first conductive units, wherein each second conductive unit has a second positive conductive structure formed on the corresponding first positive conductive layer and a second negative conductive structure formed on the corresponding first negative conductive layer.

Therefore, the photoresist layer of the related art can be replaced by the reflecting layer such as a DBR (Distributed Bragg Reflector) that is formed by plasma. The DBR can be used to reflect light source. Hence, the light-emitting efficiency of the present invention can be increased by using the DBR to increase light-reflecting efficiency, and the heat-dissipating effect of the present invention can be increased by omitting the photoresist layer of the related art to decrease heat-transmitting path.

In order to further understand the techniques, means and effects the present invention takes for achieving the prescribed objectives, the following detailed descriptions and appended drawings are hereby referred, such that, through which, the purposes, features and aspects of the present invention may be thoroughly and concretely appreciated; however, the appended drawings are provided solely for reference and illustration, without any intention that they be used for limiting the present invention.

### BRIEF DESCRIPTION OF THE DRAWINGS

FIG. 1 is a lateral, schematic view of an LED package structure of the related art;

FIG. 2 is a flowchart of a method for making a wafer level LED package structure according to the first embodiment of the present invention;

FIGS. 2A to 2J are lateral, schematic views of a wafer level LED package structure according to the first embodiment of the present invention, at different stages of the packaging processes, respectively;

FIG. 3 is a partial flowchart of a method for making a wafer level LED package structure according to the second embodiment of the present invention;

FIGS. 3A to 3C are lateral, schematic views of a wafer level LED package structure according to the second embodiment of the present invention, at different stages of the partial packaging processes, respectively; and

FIG. 4A is a lateral schematic view of a wafer level LED package structure electrically connected to and disposed on one type of a wafer substrate with at least one zener diode; and

FIG. 4B is a lateral schematic view of a wafer level LED package structure electrically connected to and disposed on another type of a wafer substrate with at least one zener diode.

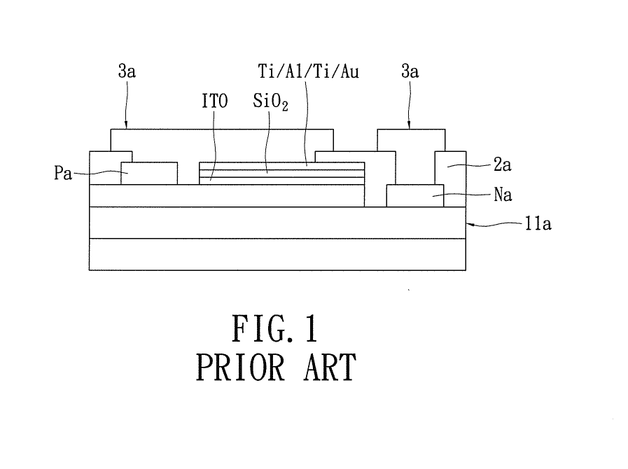

### DETAILED DESCRIPTION OF THE PREFERRED EMBODIMENTS

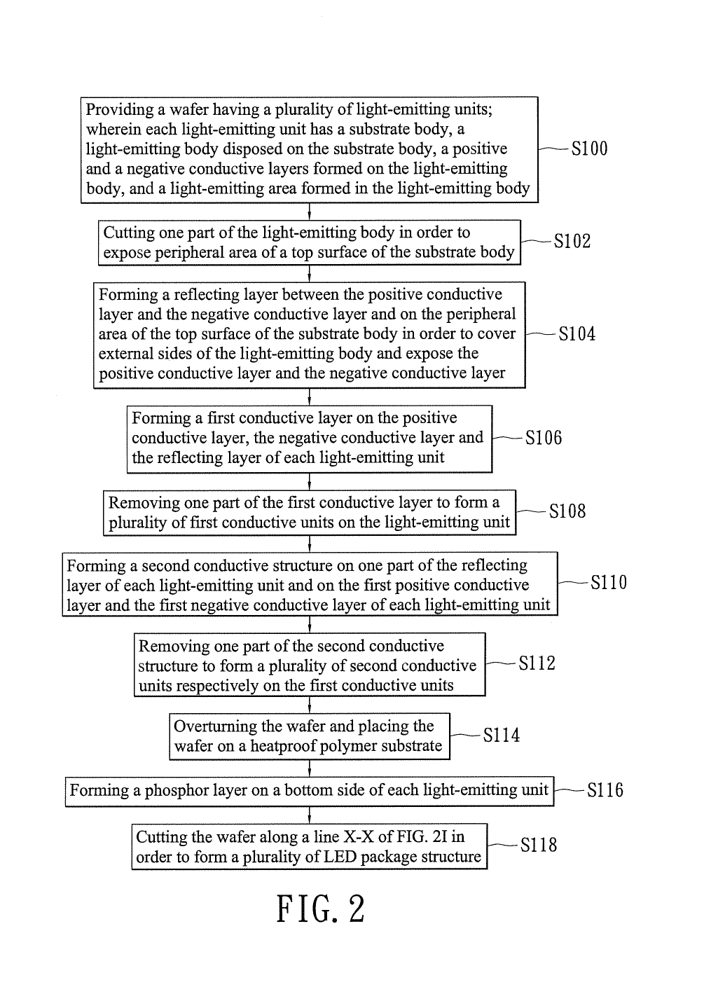

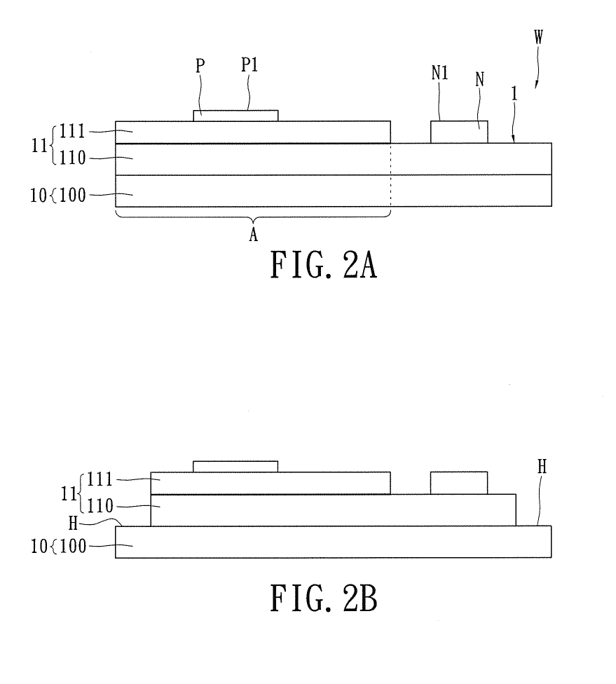

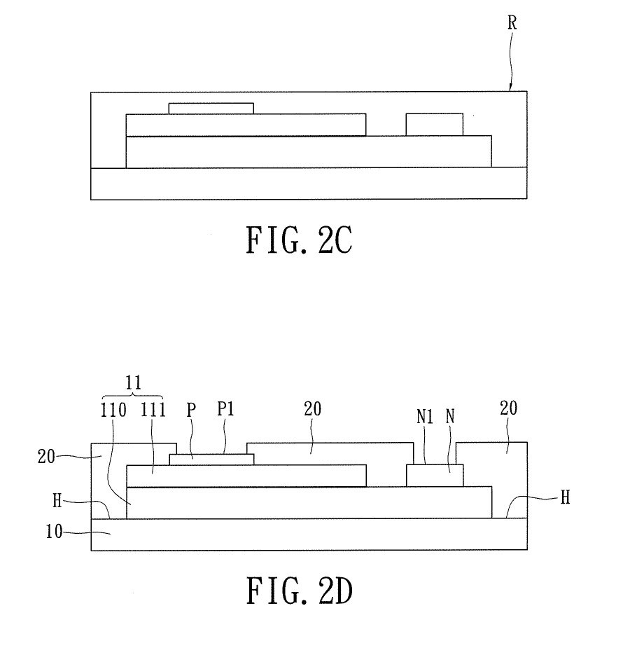

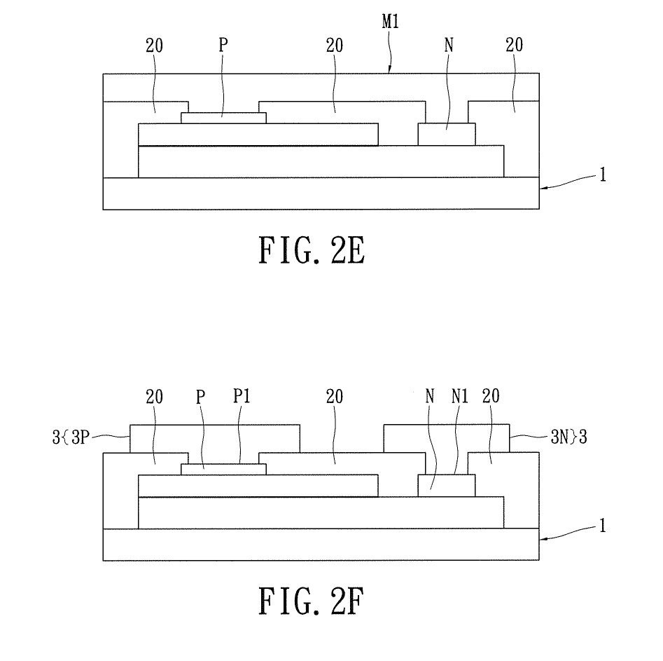

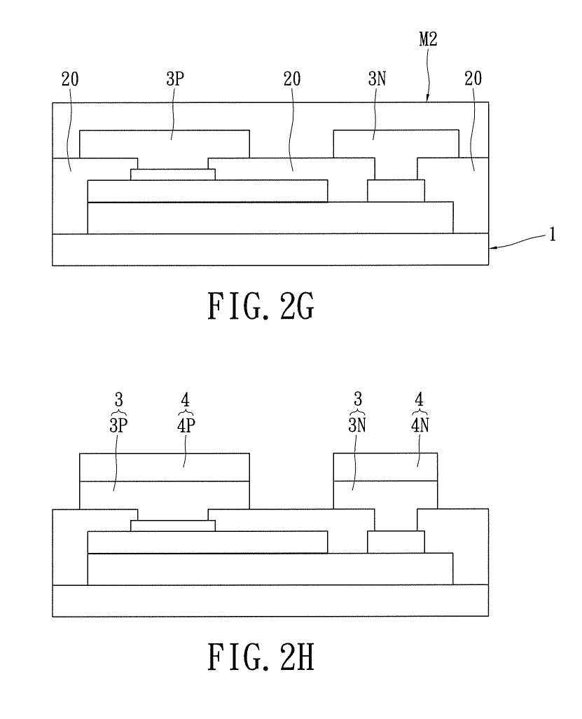

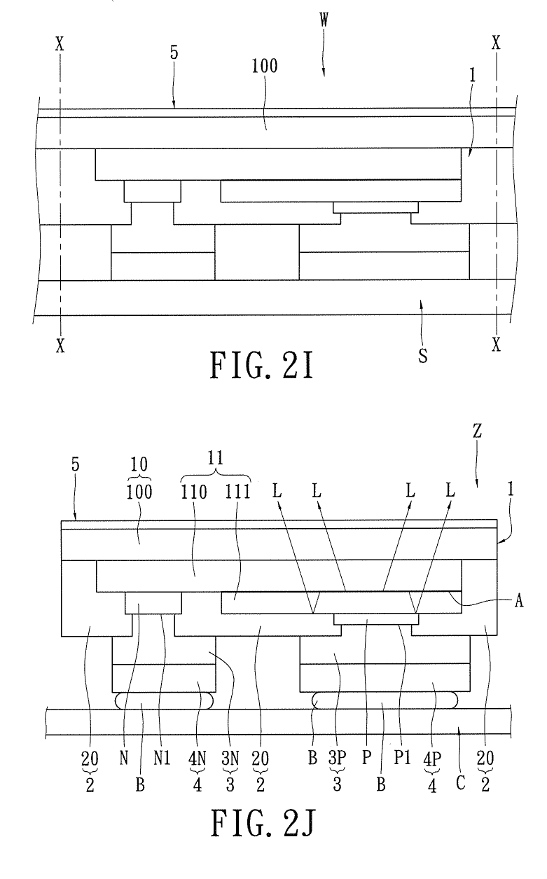

Referring to FIGS. 2 and 2A-2J, the first embodiment of the present invention provides a method for making a wafer level LED package structure for increasing light-emitting efficiency and heat-dissipating effect. The method includes following steps:

The step S100 is: referring to FIGS. 2 and 2A, providing a wafer W having a plurality of light-emitting units 1 (only shown one light-emitting units 1 in Figures), each light-emitting unit 1 having a substrate body 10, a light-emitting body 11 disposed on the substrate body 10, a positive conductive layer P (P-type semiconductor material layer) and a negative conductive layer N (N-type semiconductor material layer) both formed on the light-emitting body 11, and a light-emitting area A formed in the light-emitting body 11.

Moreover, the substrate body 11 is an Al₂O₃ substrate, and the light-emitting body 11 has a negative GaN conductive layer 110 formed on the Al₂O₃ substrate 100 and a positive GaN conductive layer 111 formed on the negative GaN conductive layer 110. The positive conductive layer P is formed on the positive GaN conductive layer 111 and the negative conductive layer N is formed on the negative GaN conductive layer 110. In addition, the positive conductive layer P has a positive conductive area P1 formed on its top surface and the negative conductive layer N has a negative conductive area N1 formed on its top surface. Light is generated from the light-emitting area A and the light-emitting area A is formed between the negative GaN conductive layer 110 and the positive GaN conductive layer 111.

The step S102 is: referring to FIGS. 2 and 2B, cutting one part of the light-emitting body 11 in order to expose peripheral area H of a top surface of the substrate body 10. In other words, when one part of the negative GaN conductive layer 110 and one part of the positive GaN conductive layer 111 are removed, the peripheral area H of the top surface of the substrate body 10 is exposed.

The step S104 is: referring to FIGS. 2 and 2C-2D, forming a reflecting layer 20 (the reflecting layer 20 is formed by etching a reflecting substance R as shown in FIGS. 2C to 2D) between the positive conductive layer P and the negative conductive layer N and on the peripheral area H of the top surface of the substrate body 10 in order to cover external sides of the light-emitting body 11 and expose the positive conductive layer P and the negative conductive layer N. In addition, the reflecting layer 20 may be made of any material with reflecting effect according to different requirements. For example, the reflecting layer 20 is a DBR (Distributed Bragg Reflector) that is formed by plasma. In other words, one part of the reflecting layer 20 is formed on one part of a top surface of the negative GaN conductive layer 110, on one part of a top surface of the positive GaN conductive layer 111 and between the positive conductive layer P and the negative conductive layer N. In addition, one part of the positive conductive area P1 and one part of the negative conductive area N1 may be coved by one part of the reflecting layer 20 according to different requirements.

The step S106 is: referring to FIGS. 2 and 2E, forming a first conductive layer M1 on the positive conductive layer P, the negative conductive layer N and the reflecting layer 20 of each light-emitting unit 1. For example, the first conductive layer M1 may be formed by electroless plating such as chemical evaporation, physical evaporation or sputtering.

The step S108 is: referring to FIGS. 2 and 2F, removing one part of the first conductive layer M1 (for example one part of the first conductive layer M1 may be removed by etching) to form a plurality of first conductive units 3 on the light-emitting unit 1. In addition, each first conductive unit 3 has a first positive conductive layer 3P formed on the positive conductive layer P and a first negative conductive layer 3N formed on the negative conductive layer N. In other words, the first positive conductive layer 3P and the first negative conductive layer 3N are insulated from each other, the first positive conductive layer 3P is formed on another part of the positive conductive area P1 and on one part of the reflecting layer 20, and the first negative conductive layer 3N is formed on another part of the negative conductive area N1 and on one part of the reflecting layer 20.

The step S110 is: referring to FIGS. 2 and 2G, forming a second conductive structure M2 on one part of the reflecting layer 20 of each light-emitting unit 1 and on the first positive conductive layer 3P and the first negative conductive layer 3N of each light-emitting unit 1. For example, the second conductive structure M2 may be formed by electroless plating such as chemical evaporation, physical evaporation or sputtering.

The step S112 is: referring to FIGS. 2 and 2H, removing one part of the second conductive structure M2 (for example one part of the second conductive structure M2 may be removed by etching) to form a plurality of second conductive units 4 respectively on the first conductive units 3. In addition, each second conductive unit 4 has a second positive conductive structure 4P formed on the first positive conductive layer 3P and a second negative conductive structure 4N formed on the first negative conductive layer 3N.

In the first embodiment, the second positive conductive structure 4P may be composed of at least three conductive layers stacked upon each other by electroplating and the second negative conductive structure 4N may be composed of at least three conductive layers stacked upon each other by electroplating. For example, the at least three conductive layers respectively may be a Copper layer (Cu), a Nickel layer (Ni) and a Gold/Tin layer (Au/Sn), the Nickel layer (Ni) is formed on the copper layer (Cu), and the Gold/Tin layer (Au/Sn) is formed on the Nickel layer (Ni).

Furthermore, in another embodiment, the second positive conductive structure 4P may be composed of at least two conductive layers stacked upon each other by electroplating and the second negative conductive structure 4N may be composed of at least two conductive layers stacked upon each other by electroplating. For example, the at least two conductive layers respectively may be a Nickel layer (Ni) and a Gold/Tin layer (Au/Sn), and the Gold/Tin layer (Au/Sn) is formed on the Nickel layer (Ni). In other words, the second positive conductive structure 4P composed of more than two conductive layers applied upon each other and the second negative conductive structure 4N composed of more than two conductive layers applied upon each other are protected in the present invention.

The step S114 is: referring to FIGS. 2 and 2I, overturning the wafer W and placing the wafer W on a heatproof polymer substrate S.

The step S116 is: referring to FIGS. 2 and 2I, forming a phosphor layer 5 on a bottom side of each light-emitting unit 1. In other words, the wafer W is overturned and the phosphor layer 5 is formed on the bottom side of the Al₂O₃ substrate 100. In addition, the phosphor layer 5 may be fluorescent resin that can be formed by mixing silicone and fluorescent powder or mixing epoxy and fluorescent powder.

The step S118 is: referring to FIGS. 2 and 2J, cutting the wafer W along a line X-X of FIG. 2I in order to form a plurality of LED package structure Z. Each LED package structure Z has a phosphor layer 5 formed on its bottom side. In addition, each LED package structure Z is electrically disposed on a PCB (Printed Circuit Board) C via at least two solder balls B. Light beams L generated from the light-generating area A of each LED package structure Z pass through the phosphor layer 5 in order to provide illumination. Furthermore, one part of the light beams generated from the light-generating area A is projected downwards and is reflected by the positive conductive layer P, the negative conductive layer N and the reflecting layer 20 in order to generate upward projecting light.

Therefore, referring to FIG. 2J, the first embodiment of the present invention provides a wafer level LED package structure Z for increasing light-emitting efficiency and heat-dissipating effect, including: a light-emitting unit 1, a reflecting unit 2, a first conductive unit 3, a second conductive unit 4 and a phosphor layer 5. In addition, the LED package structure Z is electrically disposed on a PCB C via at least two solder balls B.

Moreover, the light-emitting unit 1 has a substrate body 10, a light-emitting body 11 disposed on the substrate body 10, a positive conductive layer P and a negative conductive layer N both formed on the light-emitting body 11, and a light-emitting area A formed in the light-emitting body 11. In addition, the substrate body 11 is an Al₂O₃ substrate, and the light-emitting body 11 has a negative GaN conductive layer 110 formed on the Al₂O₃ substrate 100 and a positive GaN conductive layer 111 formed on the negative GaN conductive layer 110. The positive conductive layer P is formed on the positive GaN conductive layer 111 and the negative conductive layer N is formed on the negative GaN conductive layer 110. The positive conductive layer P has a positive conductive area P1 formed on its top surface and the negative conductive layer N has a negative conductive area N1 formed on its top surface.

Furthermore, the reflecting unit 2 has a reflecting layer 20 formed between the positive conductive layer P and the negative conductive layer N and on the substrate body 10 for covering external sides of the light-emitting body 11. In addition, the reflecting layer 20 may be made of any material with reflecting effect according to different requirements. For example, the reflecting layer 20 is a DBR (Distributed Bragg Reflector) that is formed by plasma. In other words, one part of the reflecting layer 20 is formed on one part of a top surface of the negative GaN conductive layer 110, on one part of a top surface of the positive GaN conductive layer 111 and between the positive conductive layer P and the negative conductive layer N. In addition, one part of the positive conductive area P1 and one part of the negative conductive area N1 may be coved by one part of the reflecting layer 20 according to different requirements.

Besides, the first conductive unit 3 has a first positive conductive layer 3P formed on the positive conductive layer P and a first negative conductive layer 3N formed on the negative conductive layer N. In other words, the first positive conductive layer 3P and the first negative conductive layer 3N are insulated from each other, the first positive conductive layer 3P is formed on another part of the positive conductive area P1 and on one part of the reflecting layer 20, and the first negative conductive layer 3N is formed on another part of the negative conductive area N1 and on one part of the reflecting layer 20.

Moreover, the first conductive unit 4 has a second positive conductive structure 4P formed on the first positive conductive layer 3P and a second negative conductive structure 4N formed on the first negative conductive layer 3N. In the first embodiment, the second positive conductive structure 4P may be composed of at least three conductive layers stacked upon each other by electroplating and the second negative conductive structure 4N may be composed of at least three conductive layers stacked upon each other by electroplating. For example, the at least three conductive layers respectively may be a Copper layer (Cu), a Nickel layer (Ni) and a Gold/Tin layer (Au/Sn), the Nickel layer (Ni) is formed on the copper layer (Cu), and the Gold/Tin layer (Au/Sn) is formed on the Nickel layer (Ni).

Furthermore, in another embodiment, the second positive conductive structure 4P may be composed of at least two conductive layers stacked upon each other by electroplating and the second negative conductive structure 4N may be composed of at least two conductive layers stacked upon each other by electroplating. For example, the at least two conductive layers respectively may be a Nickel layer (Ni) and a Gold/Tin layer (Au/Sn), and the Gold/Tin layer (Au/Sn) is formed on the Nickel layer (Ni). In other words, the second positive conductive structure 4P composed of more than two conductive layers applied upon each other and the second negative conductive structure 4N composed of more than two conductive layers applied upon each other are protected in the present invention.

In addition, the phosphor layer 5 is formed on the bottom side of the light-emitting unit 1. In other words, the phosphor layer 5 formed on the bottom side of the Al₂O₃ substrate 100 mates with the light beams L generated from light-emitting area A in order to provide white light.

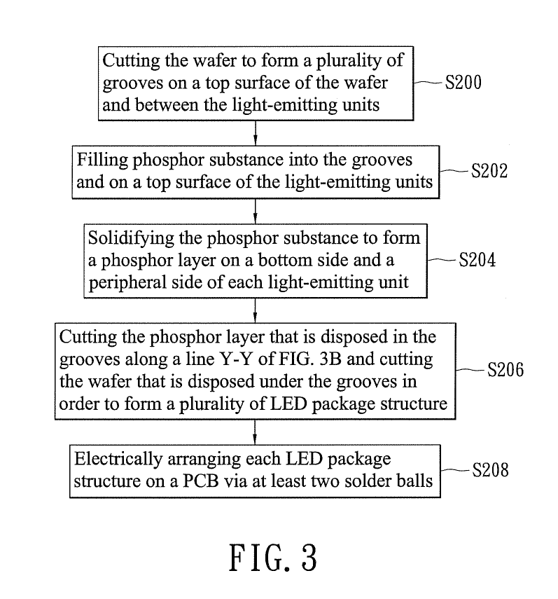

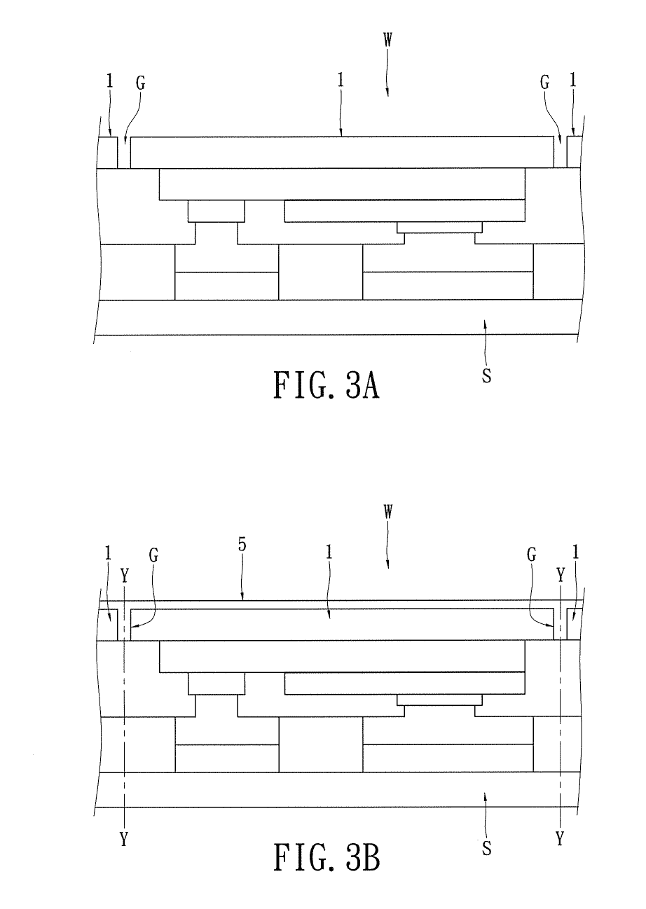

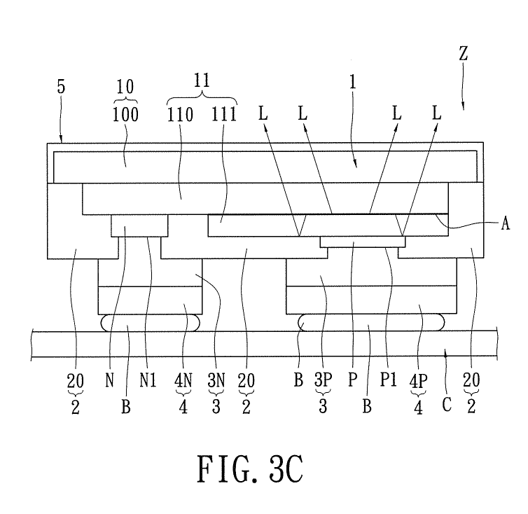

Referring to FIGS. 3 and 3A-3C, the difference between the second embodiment and the first embodiment is that: after the step of overturning the wafer W and placing the wafer W on a heatproof polymer substrate S, the method of the second embodiment further includes following steps:

The step S200 is: referring to FIGS. 3 and 3A, cutting the wafer W to form a plurality of grooves G on a top surface of the wafer W and between the light-emitting units 1.

The step S202 is: referring to FIGS. 3 and 3B, filling phosphor substance (not shown) into the grooves G and on a top surface of the light-emitting units 1. In addition, the phosphor substance is fluorescent resin that can be formed by mixing silicone and fluorescent powder or mixing epoxy and fluorescent powder.

The step S204 is: referring to FIGS. 3 and 3B, solidifying the phosphor substance to form a phosphor layer 5 on a bottom side and a peripheral side of each light-emitting unit 1.

The step S206 is: referring to FIGS. 3 and 3B, cutting the phosphor layer 5 that is disposed in the grooves G along a line Y-Y of FIG. 3B and cutting the wafer W that is disposed under the grooves G in order to form a plurality of LED package structure Z.

The step S208 is: referring to FIGS. 3 and 3C, electrically arranging each LED package structure Z on a PCB C via at least two solder balls (or solder glue) B. Light beams L generated from the light-generating area A of each LED package structure Z pass through the phosphor layer 5 in order to provide illumination.

Therefore, referring to FIG. 3C, the difference between the second embodiment and the first embodiment is that: in the second embodiment, the phosphor layer 5 is formed on the bottom side and the peripheral side of the light-emitting unit 1 or on the bottom side and the peripheral side of each LED package structure Z in order to mate with the light beams L generated from light-emitting area A for providing white light.

In conclusion, the present invention has the following advantages:

1. The photoresist layer of the related art can be replaced by the reflecting layer 20 such as a DBR (Distributed Bragg Reflector) that is formed by plasma. The DBR can be used to reflect light source. Hence, the light-emitting efficiency of the present invention can be increased by using the DBR to increase light-reflecting efficiency, and the heat-dissipating effect of the present invention can be increased by omitting the photoresist layer of the related art to decrease heat-transmitting path.

2. With regards to the first embodiment, the phosphor layer 5 formed on the bottom side of the Al₂O₃ substrate 100 mates with the light beams L generated from light-emitting area A in order to provide white light. With regards to the second embodiment, the phosphor layer 5 is formed on the bottom side and the peripheral side of the light-emitting unit 1 in order to mate with the light beams L generated from light-emitting area A for providing white light.

3. The external area of the light-emitting body 11 of the light-emitting unit 1 is covered by the reflecting layer 20 of the reflecting unit 2 in order to protect the external area of the light-emitting unit 1.

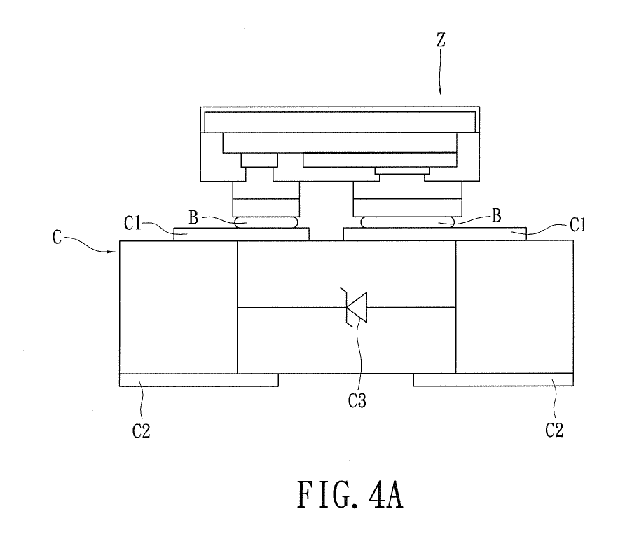

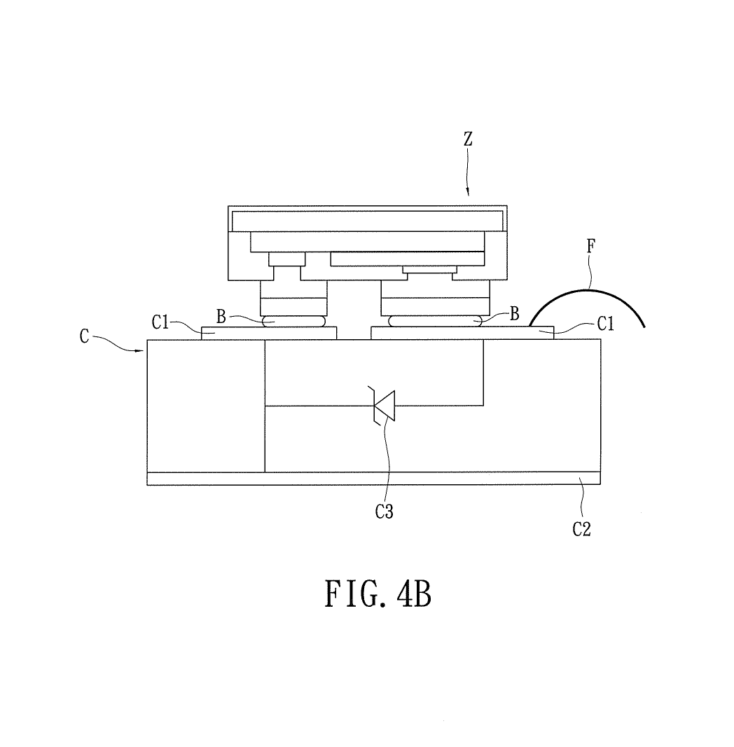

Referring to FIG. 4A, the present invention provides a wafer substrate C that has at least two top conductive pads C1 formed on a top surface thereof, at least two bottom conductive pads C2 formed on a bottom surface thereof and respectively connected to the at least two top conductive pads C1, and at least one built-in zener diode C3 disposed therein. The wafer level LED package structure Z may be disposed on and electrically connected to the wafer substrate C via at least two solder balls (or solder glue) B. In other words, the two electrodes of the wafer level LED package structure Z are respectively and electrically connected to the at least two top conductive pads C1 via the at least two solder balls B, thus the two electrodes of the wafer level LED package structure Z are respectively and electrically connected to the at least two bottom conductive pads C2.

Referring to FIG. 4B, the present invention provides a wafer substrate C that has at least two top conductive pads C1 formed on a top surface thereof, at least one bottom conductive pads C2 formed on a bottom surface thereof and connected to one of the at least two top conductive pads C1, and at least one built-in zener diode C3 disposed therein. The wafer level LED package structure Z may be disposed on and electrically connected to the wafer substrate C via at least two solder balls (or solder glue) B. In other words, the two electrodes of the wafer level LED package structure Z are respectively and electrically connected to the at least two top conductive pads C1 via the at least two solder balls B, and one of the two electrodes of the wafer level LED package structure Z is electrically connected to the at least one bottom conductive pads C2 and the other of the two electrodes of the wafer level LED package structure Z is electrically connected to at least one conductive wire F.

The above-mentioned descriptions merely represent solely the preferred embodiments of the present invention, without any intention or ability to limit the scope of the present invention which is fully described only within the following claims. Various equivalent changes, alterations or modifications based on the claims of present invention are all, consequently, viewed as being embraced by the scope of the present invention.

What is claimed is:

1. A method for making a wafer level LED package structure for increasing light-emitting efficiency and heat-dissipating effect, comprising:
providing a wafer having a plurality of light-emitting units, wherein each light-emitting unit has a substrate body, a light-emitting body disposed on the substrate body, a positive conductive layer and a negative conductive layer both formed on the light-emitting body, and a light-emitting area formed in the light-emitting body;
cutting one part of the light-emitting body in order to expose peripheral area of a top surface of the substrate body;
forming a reflecting layer between the positive conductive layer and the negative conductive layer and on the peripheral area of the top surface of the substrate body in order to cover external sides of the light-emitting body and expose the positive conductive layer and the negative conductive layer;
respectively forming a plurality of first conductive units on the light-emitting units, wherein each first conductive unit has a first positive conductive layer formed on the corresponding positive conductive layer and a first negative conductive layer formed on the corresponding negative conductive layer; and
respectively forming a plurality of second conductive units on the first conductive units, wherein each second conductive unit has a second positive conductive structure formed on the corresponding first positive conductive layer and a second negative conductive structure formed on the corresponding first negative conductive layer.

2. The method as claimed in claim 1, wherein the substrate body is an Al₂O₃ substrate, and the light-emitting body has a negative GaN conductive layer formed on the Al₂O₃ substrate and a positive GaN conductive layer formed on the negative GaN conductive layer; the positive conductive layer is formed on the positive GaN conductive layer, the negative conductive layer is formed on the negative GaN conductive layer, and one part of the reflecting layer is formed on one part of a top surface of the negative GaN conductive layer, on one part of a top surface of the positive GaN conductive layer and between the positive conductive layer and the negative conductive layer.

3. The method as claimed in claim 1, wherein the positive conductive layer has a positive conductive area formed on a top surface thereof, the negative conductive layer has a negative conductive area formed on a top surface thereof, and one part of the positive conductive area and one part of the negative conductive area are covered by one part of the reflecting layer.

4. The method as claimed in claim 3, wherein the first positive conductive layer and the first negative conductive layer are insulated from each other, the first positive conductive layer is formed on another part of the positive conductive area and on one part of the reflecting layer, and the first negative conductive layer is formed on another part of the negative conductive area and on one part of the reflecting layer.

5. The method as claimed in claim 1, wherein the reflecting layer is a DBR (Distributed Bragg Reflector) that is formed by plasma.

6. The method as claimed in claim 1, wherein the second positive conductive structure is composed of at least two conductive layers stacked upon each other by electroplating, the second negative conductive structure is composed of at least two conductive layers stacked upon each other by electroplating, the at least two conductive layers respectively are a Nickel layer and a Gold/Tin layer, and the Gold/Tin layer is formed on the Nickel layer.

7. The method as claimed in claim 1, wherein the second positive conductive structure is composed of at least three conductive layers stacked upon each other by electroplating, the second negative conductive structure is composed of at least three conductive layers stacked upon each other by electroplating, the at least three conductive layers respectively are a Copper layer, a Nickel layer and a Gold/Tin layer, the Nickel layer is formed on the copper layer, and the Gold/Tin layer is formed on the Nickel layer.

8. The method as claimed in claim 1, wherein the step of respectively forming the first conductive units on the light-emitting units further comprises:
forming a first conductive layer on the positive conductive layer, the negative conductive layer and the reflecting layer of each light-emitting unit; and
removing one part of the first conductive layer to form the first positive conductive layer and the first negative conductive layer of each first conductive unit.

9. The method as claimed in claim 8, wherein the first conductive layer is formed by electroless plating such as evaporation or sputtering, and one part of the first conductive layer is removed by etching.

10. The method as claimed in claim 1, wherein the step of respectively forming the second conductive units on the first conductive units further comprises:
forming a second conductive structure on one part of the reflecting layer of each light-emitting unit and on the first positive conductive layer and the first negative conductive layer of each light-emitting unit; and
removing one part of the second conductive structure to form the second positive conductive structure and the second negative conductive structure of each second conductive unit.

11. The method as claimed in claim 1, wherein after the step of respectively forming a plurality of second conductive units on the first conductive units, the method further comprises:
overturning the wafer and placing the wafer on a heatproof polymer substrate;
forming a phosphor layer on a bottom side of each light-emitting unit; and
cutting the wafer in order to form a plurality of LED package structure.

12. The method as claimed in claim 1, wherein after the step of respectively forming a plurality of second conductive units on the first conductive units, the method further comprises:
overturning the wafer and placing the wafer on a heatproof polymer substrate;
cutting the wafer to form a plurality of grooves on a top surface of the wafer and between the light-emitting units;
filling phosphor substance into the grooves and on a top surface of the light-emitting units;
solidifying the phosphor substance to form a phosphor layer on a bottom side and a peripheral side of each light-emitting unit; and
cutting the phosphor layer that is disposed in the grooves and cutting the wafer that is disposed under the grooves in order to form a plurality of LED package structure.
